(19) United States
(12) Patent Application Publication
(10) Pub. No.: US 2015/0118834 A1
(43) Pub. Date: Apr. 30, 2015

(54) SULFUR AND SELENIUM PASSIVATION OF SEMICONDUCTORS

(71) Applicant: Sematech, Inc., Albany, NY (US)

(72) Inventors: Wei-Yip LOH, Loudonville, NY (US); Robert TIECKELMANN, Clifton Park, NY (US)

(73) Assignee: Sematech, Inc., Albany, NY (US)

(21) Appl. No.: 14/524,615

(22) Filed: Oct. 27, 2014

Related U.S. Application Data
(60) Provisional application No. 61/895,473, filed on Oct. 25, 2013.

(51) Int. Cl. H01L 21/225; H01L 21/324; H01L 21/02

(52) U.S. Cl. CPC H01L 21/2258; H01L 21/02112; H01L 21/02362; H01L 21/3245; H01L 21/0217
USPC 438/559; 438/779

(57) ABSTRACT

The present invention includes methods directed to improved processes for producing a monolayer of sulfur or selenium on the surface of a semiconductor. As a surface layer, it functions to passivate the surface; if annealed, it provides a doping element.

### CROSS REFERENCE TO RELATED APPLICATIONS

This application claims priority to U.S. Provisional Application No. 61/895,473 filed Oct. 25, 2013, the entire contents of which are hereby incorporated herein by reference.

### TECHNICAL FIELD

The present invention is directed toward an improved process for creating a sulfur or selenium monolayer on the surface of a semiconductor material.

### BACKGROUND OF THE INVENTION

As semiconductor technology moves toward ever faster and smaller devices, new challenges arise. In particular, when contemplating devices that require shallow (<9 nm) defect-free extensions, conventional techniques fall short. Cluster implantation, plasma immersion ion implantation and solid phase epitaxial regrowth are known for sub-micron device fabrication, but their use to make nanoscale devices is problematic. Monolayer doping is an established technique for controlling the doping of nanometer scale surfaces. [See Ho et al., Nature Materials 7, 62-67 (2008); Ho et al., Nano Letters 9, 725-730 (2009) and PCT WO2011/112546]. Similarly, passivation of GaAs semiconductors with sulfur and selenium is known [see Bessolov and Lebedev Semiconductors 32, 1141-1156 (1998)]. Unfortunately, the known means for providing a monolayer are not uniformly attractive. Solution passivation with ammonium sulfide on binary and ternary semiconductors is known, but most procedures described in the literature require the use and disposal of industrial quantities of 20% aqueous (NH₄)₂Sₓ. Ammonium polysulfide and its precursor, ammonium sulfide, are toxic; both storage and disposal raise safety issues. Twenty percent aqueous ammonium sulfide and polysulfide must be stored under the most stringent conditions and, after use, must be disposed of by collection and off-site decontamination. Contact with acidifying substances in wastewater generates hydrogen sulfide, which is itself volatile, offensive and toxic. There is a general need for a process for producing a sulfur monolayer on a semiconductor, which process is practical on an industrial scale.

Solutions of ammonium selenide are not easily handled and not available commercially. This adds an additional level of difficulty for selenium passivation.

Thus, a need exists for an improved process for creating a sulfur or selenium monolayer on the surface of a semiconductor material.

While certain aspects of conventional technologies have been discussed to facilitate disclosure of the invention, Applicant in no way disclaims these technical aspects, and it is contemplated that the claimed invention may encompass one or more of the conventional technical aspects discussed herein.

In this specification, where a document, act or item of knowledge is referred to or discussed, this reference or discussion is not an admission that the document, act or item of knowledge or any combination thereof was, at the priority date, publicly available, known to the public, part of common general knowledge, or otherwise constitutes prior art under the applicable statutory provisions; or is known to be relevant to an attempt to solve any problem with which this specification is concerned.

### SUMMARY OF THE INVENTION

Briefly, the present invention satisfies the need for improved processes for creating a sulfur or selenium monolayer on the surface of a semiconductor material. More particularly, the present invention relates to an improved process for passivating a IV or III-V semiconductor material with sulfur or selenium. The process produces a monolayer of sulfur or selenium on the surface of a semiconductor. As a surface layer, it functions to passivate the surface. If annealed, it provides a doping element. The present invention may address one or more of the problems and deficiencies of the art discussed above. However, it is contemplated that the invention may prove useful in addressing other problems and deficiencies in a number of technical areas. Therefore, the claimed invention should not necessarily be construed as limited to addressing any of the particular problems or deficiencies discussed herein.

In one aspect, the invention provides a method for passivating a IV or III-V semiconductor material. The method includes exposing said material to an aqueous solution of a sulfur compound at a concentration between 0.001M and 10 M, wherein said sulfur compound is selected from a covalent sulfur compound, ammonium thiosulfate, and ammonium sulfite.

In another aspect, the invention provides a method for making an n-region in a semiconductor, the method comprising:

(a) providing a IV or III-V semiconductor material substrate;

(b) exposing said material to an aqueous solution of a sulfur compound at a concentration between 0.001M and 10 M to provide a semiconductor material having a surface layer containing sulfur, wherein said sulfur compound is selected from a covalent sulfur compound, ammonium thiosulfate, and ammonium sulfite;

(c) capping said surface layer containing sulfur; and

(d) annealing said semiconductor material having a capped surface layer containing sulfur, whereby sulfur diffuses into said IV or III-V semiconductor material.

In another aspect, the invention provides a method for passivating a IV or III-V semiconductor material, said method comprising exposing said material to an aqueous solution of a covalent selenium compound at a concentration between 0.001M and 10 M.

In another aspect, the invention provides a method for making an n-region in a semiconductor, said method comprising:

(a) providing a IV or III-V semiconductor material substrate;

(b) exposing said material to an aqueous solution of a covalent selenium compound at a concentration between 0.001M and 10 M to provide a semiconductor material having a surface layer containing selenium;

(c) capping said surface layer containing selenium; and

(d) annealing said semiconductor material having a capped surface layer containing selenium, whereby selenium diffuses into said IV or III-V semiconductor material.

### BRIEF DESCRIPTION OF THE DRAWINGS

FIG. 1 shows a secondary ion mass spectrometry depth profile for results of testing performed on embodiments of inventive methods utilizing dopant solutions comprising polysulfides, cysteine, (NH₄)₂S, and (NH₄)₂₅₂O₃.

### DETAILED DESCRIPTION OF THE INVENTION

The present invention is generally directed to improved processes for creating a sulfur or selenium monolayer on the surface of a semiconductor material.

Although this invention is susceptible to embodiment in many different forms, certain embodiments of the invention are shown and described. It should be understood, however, that the present disclosure is to be considered as an exemplification of the principles of this invention and is not intended to limit the invention to the embodiments illustrated.

The invention relates to monolayer deposition (MLD) methods employing sulfur- and selenium-containing materials that, in various embodiments, are generally common, reasonably non-toxic, and relatively non-volatile. Many of the compounds set forth herein that can be used to form monolayers are soluble in aqueous solution and many of the compounds and their aqueous solutions are stable in air and at room temperature. Moreover, several compounds do not exhibit sufficient vapor pressure to create an offensive odor or other hazard when dissolved in water, even at relatively high concentration.

The use of concentrated and diluted solutions of ammonium sulfide and ammonium sulfide/polysulfide for passivating Group III-V surfaces is well documented. In these aqueous solutions, the sulfide anion (S²⁻) and polysulfide anions (Sₙ²⁻, where n=2, 3, 4, 5, 6, 7 or 8) interact with the semiconductor surface and form a bond. For selenium passivation, both elemental selenium and tin selenide are known sources of selenium.

However, the present invention relates to the discovery that other sulfur-containing and selenium-containing compounds are similarly reactive and have similar affinity for the semiconductor surface. The range of candidates is broad. These compounds are both inorganic and organic in nature and are used in common applications such as personal care products (ammonium thiosulfate in hair shampoos), vitamin supplements (semi-essential amino acids such as cysteine), common reducing agents (ammonium sulfite is used in cosmetic, food, and photography applications) and naturally occurring amino acids (selenomethionine is found in nuts, cereal grains and soybeans).

Examples of candidates for sulfur passivation include: cystine, cysteine, homocysteine, dimethyl sulfide, methionine, thiourea, trithiane, Lawesson's Reagent [2,4-bis(4-methoxyphenyl)-1,3,2,4-dithiadiphosphetane-2,4-dithione], thiophenol, benzyl mercaptan, diallyl sulfide, dimethyl disulfide, and triphenylphosphine sulfide. In general the sources of sulfur are covalent compounds in which sulfur is divalent and is attached to at least one carbon. They fall into the general classes of organic thiols, sulfides and disulfides. In addition to organic thiols, sulfides and disulfides, ammonium thiosulfate and ammonium sulfite may function as sulfur sources for MLD. In some embodiments, the covalent sulfur compound consists of sulfur, carbon and from one to three additional elements chosen from hydrogen, oxygen and nitrogen. Usually, the oxygen or nitrogen, when present, will not be directly bonded to the sulfur. In some embodiments the covalent sulfur compound is an organic mercaptan (thiol) or thioether. In some embodiments the mercaptan or thioether is a naturally occurring aminoacid

Examples of candidates for selenium passivation include: benzeneselenol, dimethyldiselenide, dimethylselenourea, diphenyldiselenide, diphenylselenide, p-tolylselenide, selenium sulfide, selenocystine, selenocysteine, selenomethionine, selenourea, diallyl selenide, triphenylphosphine selenide, and Woollins' Reagent [2,4-diphenyl-1,3,2,4-diselenadiphosphetan-2,4-diselenide]. In general the sources of selenium are covalent compounds in which selenium is divalent and is attached to at least one carbon. They fall into the general classes of organic selenols, selenides and diselenides. In some embodiments, the covalent selenium compound consists of selenium, carbon and from one to three additional elements chosen from hydrogen, oxygen and nitrogen. In some embodiments the covalent selenium compound is an organic selenol or selenium ether. In some embodiments the selenol or selenium ether is a naturally occurring amino acid.

In one aspect, the invention provides a method for passivating a IV or III-V semiconductor material. The method includes exposing said material to an aqueous solution of a sulfur compound at a concentration between 0.001M and 10 M, wherein said sulfur compound is selected from a covalent sulfur compound, ammonium thiosulfate, and ammonium sulfite.

The semiconductors that are the substrates (i.e., the semiconductor material) for the process of the invention are known in the art as IV and III-V semiconductors.

IV semiconductor materials are those comprising at least one atom of a Group IV element. Examples of common IV semiconductor materials are silicon, germanium and silicon-germanium.

III-V semiconductor materials are those comprising at least one atom of a Group III element and at least one atom of a Group V element. Examples of common III-V semiconductor materials are those which include GaAs, InP, InAs, GaP, InGaAs, InAlAs, InAlGa and GalnP. Examples of other, less common binary and ternary III-V materials include: AlSb, GaSb, GaP, InSb, AlGaAs, GaAsP, InGaN. For some uses quaternary III-V materials, such as those including AlGaInP and InGaAsSb, can be employed. The binary, ternary and quaternary alloys of GaAs, InP, InAs and GaP are preferred. The InAs/GaAs ternary alloy can be characterized as InₓGa₁₋ₓAs where x is the proportion of InAs and ₁₋ₓ is the proportion of GaAs. A convenient substrate for InₓGa₁₋ₓAs is InP. Accordingly, InGaAs layers have been disposed over InP layers in semiconductor structures, but such structures differ from the present invention, where an InP interlayer is disposed over the III-V semiconductor material (e.g., the InGaAs), between the III-V material and a metal alloy layer, M(InP)(InGaAs). Since InₓGa₁₋ₓAs with 53% InAs has the same lattice constant as InP, the combination leads to very high quality thin films, and InₓGa₁₋ₓAs with 53% InAs is often called “standard InGaAs” without bothering to note the values of “ₓ” or “₁₋ₓ”. When a specific sample of InGaAs is described in the experiments below, it will be standard InGaAs unless otherwise noted.

In some embodiments, the semiconductor material is chosen from Si, Ge, SiGe, GaAs, InP, InAs, GaP and ternary and quaternary alloys of GaAs, InP, InAs and GaP. In particular embodiments, the semiconductor material is chosen from InGaAs and GaAs.

The inventive method includes exposing the IV or III-V semiconductor material to an aqueous solution of a sulfur compound at a concentration between 0.001M and 10 M, including any and all ranges and subranges therein (e.g., at a concentration of from 0.005 to 5 M, 0.1 to 4 M, 0.5 to 3 M, etc.). For example, in some embodiments, the concentration of the sulfur compound in the aqueous solution is 0.002, 0.004, 0.006, 0.008, 0.01, 0.02, 0.03, 0.04, 0.05, 0.06, 0.07, 0.08, 0.09, 0.1, 0.2, 0.3, 0.4, 0.5, 0.6, 0.7, 0.8, 0.9, 1, 1.5, 2, 2.5, 3, 3.5, 4, 4.5, 5, 5.5, 6, 6.5, 7, 7.5, 8, 8.5, 9, 9.5, or 10 M.

The sulfur compound is selected from a covalent sulfur compound, ammonium thiosulfate, and ammonium sulfite.

In some embodiments, the sulfur compound is a covalent sulfur compound. For example, in some embodiments, the sulfur compound is a covalent sulfur compound that consists of sulfur, carbon, and from one to three additional elements chosen from hydrogen, oxygen and nitrogen. In some embodiments, the covalent sulfur compound is an organic mercaptan or thioether. In particular embodiments, said mercaptan or thioether is a naturally occurring amino acid.

In some embodiments, the sulfur compound is cysteine.

In other embodiments, the sulfur compound is selected from ammonium thiosulfate and ammonium sulfite.

The sulfur or selenium monolayer created by the process described herein can be whatever thickness is desired. In most cases the desired thickness is from 5 Å to 50 Å (e.g., 5, 10, 15, 20, 25, 30, 35, 40, 45, or 50 Å), including any and all ranges and subranges therein. For example, in some embodiments, the thickness is 10 Å to 20 Å thick.

The sulfur or selenium monolayer can be left in place as a passivation layer, or the structure can be annealed to disperse the sulfur or selenium into the substrate and create an n-region of defined morphology. In some embodiments where the coated substrate is to be annealed, the sulfur or selenium layer is capped so as to prevent its loss by vaporization during annealing. In various embodiments, such capping ensures that substantially all of the sulfur or selenium that has been deposited diffuses into the substrate rather than only a portion thereof diffusing into the substrate.

Capping materials are known in the art, and include materials that are typically used as a chemical barrier. Nitrides and oxides that can be conformally-coated function in this capacity, and fall within the scope of capping materials as discussed herein. For example, in some embodiments, the capping material is selected from silicon oxide and silicon nitride.

In some embodiments, the inventive methods comprise, after forming the layer of sulfur or selenium on the surface of the semiconductor material, capping the layer of S or Se with a capping material, and then subsequently diffusing the S or Se into the semiconductor material, for example, by annealing.

Annealing is known in the art. Where diffusion is achieved via annealing, inventive embodiments encompass any desired annealing capable of diffusing the dopant into the silicon material, including both convention and non-conventional annealing, such as flash anneal, spike anneal, microwave anneal, laser anneal, or soak anneal Annealing may be carried out at any desirable diffusion-achieving temperature. Annealing is commonly carried out, e.g., in an inert atmosphere such as helium or argon, at temperatures e.g., from 300° C. to 1100° C. In certain embodiments for III-V materials, the temperatures are, e.g., from 400° C. to 800° C. In certain embodiments the substrate may be annealed for, e.g., a period of 1 millisecond to 60 minutes (including any and all ranges and subranges therein, e.g., 1-60 seconds). The expression “from temperature x to temperature y”, e.g. “from 300° C. to 1100° C.”, means that the process is carried out either by maintaining any temperature between 300° C. and 1100° C. or by varying the temperature within that range. In some embodiments, the annealing is carried out at a temperature of 400° C. to 1100° C., for example, 400, 450, 475, 500, 525, 550, 575, 600, 625, 650, 675, 700, 725, 750, 775, 800, 825, 850, 875, 900, 925, 950, 975, 1000, 1025, 1050, 1075, or 1100° C., including any and all ranges and subranges therein.

In another aspect, the invention provides a method for making an n-region in a semiconductor, the method comprising:

(a) providing a IV or III-V semiconductor material substrate;

(b) exposing said material to an aqueous solution of a sulfur compound at a concentration between 0.001M and 10 M to provide a semiconductor material having a surface layer containing sulfur, wherein said sulfur compound is selected from a covalent sulfur compound, ammonium thiosulfate, and ammonium sulfite;

(c) capping said surface layer containing sulfur; and

(d) annealing said semiconductor material having a capped surface layer containing sulfur, whereby sulfur diffuses into said IV or III-V semiconductor material.

An n-region is a region which has been doped with dopant atoms (e.g., S or Se) capable of providing extra conduction electrons to the host material, thereby creating an excess of negative (n-type) electron charge carriers. Any acceptable n-type dopant atoms may be used.

Where semiconductor materials, layers, and structures are referred to throughout the disclosure and claims, unless otherwise indicated, the materials, layers, or structures may contain various dopants or other additives. Doping processes are well-known by persons having ordinary skill in the art, and any acceptable doping processes may be used in the fabrication of materials, layers, and substrates of the present invention. For example, dopants may be incorporated into semiconductor materials in various ways, including, but not limited to, MBE (molecular beam epitaxy), MOCVD (metalorganic chemical vapor deposition), MLD (monolayer deposition), and traditional ion implantation (I/I).

In another aspect, the invention provides a method for passivating a IV or III-V semiconductor material, said method comprising exposing said material to an aqueous solution of a covalent selenium compound at a concentration between 0.001M and 10 M.

In some embodiments, the covalent selenium compound consists of selenium, carbon and from one to three additional elements chosen from hydrogen, oxygen and nitrogen. In some embodiments, the covalent selenium compound is an organic selenol or selenium ether. In some embodiments, the covalent selenium compound is seleno-DL-methionine.

In another aspect, the invention provides a method for making an n-region in a semiconductor, said method comprising:

(a) providing a IV or III-V semiconductor material substrate;

(b) exposing said material to an aqueous solution of a covalent selenium compound at a concentration between 0.001M and 10 M to provide a semiconductor material having a surface layer containing selenium;

(c) capping said surface layer containing selenium; and

(d) annealing said semiconductor material having a capped surface layer containing selenium, whereby selenium diffuses into said IV or III-V semiconductor material.

### EXAMPLES

The invention will now be illustrated, but not limited, by reference to the specific embodiments described in the following examples.

The substrates used in the examples were standard InGaAs. Surface oxide was first removed by a 30 second to 3-minute dip in aqueous HF (10:1 or 1000:1) at room temperature followed by a dip rinse in H₂O. Passivation was carried out at room temperature by dipping the substrate in the solutions at the concentrations shown below for 1 to 10 minutes followed by a dip rinse in H₂O. The sulfur or selenium was capped by physical vapor deposition (sputtering) of a 200 Å film of silicon nitride using a single crystal silicon target doped with phosphorus (99.999% purity) and a flow rate of argon 35 SCCM and nitrogen 36 SCCM at 300 W power at ambient temperature. The capped substrates were annealed under argon at 400° C. to 800° C. for 30 seconds. Results are shown in Table 1.

While the substrates used in all examples were standard InGaAs substrates, the specific substrate used in a given example may have come from a manufacturing run different from that of other examples.

TABLE 1

| | HF | | | Solute | | | Sheet | | Dopant |
|---|---|---|---|---|---|---|---|---|---|
| Ex- | (1:100) | | | Concen- | MLD | | Resistance | Electron | Concen- |
| am- | Dip | | Sol- | tration | Time | | Rₛₕ | Mobility | tration |
| ples | (sec) | S-MLD Solute in DIW | vent | (mole/liters) | (min) | Rinse | (ohm/sq) | (cm² V⁻¹s⁻¹) | (1 × 10¹² cm⁻²) |
| 1 | 30 s | Ammonium Sulfide + | DIW | 2 | 1 | DIW | 161.1 | 2335 | −16.66 |
| | | S (S₈) powder | | | | | | | |
| 2 | 30 s | Ammonium Sulfide + | DIW | 2 | 5 | DIW | 127.5 | 2373 | −19.07 |
| | | S (S₈) powder | | | | | | | |
| 3 | 30 s | Ammonium Sulfide + | DIW | 2 | 10 | DIW | 161.2 | 1890.0 | −20.50 |
| | | S (S₈) powder | | | | | | | |
| 5 | 30 s | Ammonium sulfite | DIW | 2 | 3 | DIW | 1527 | 1439 | −2.94 |
| 6 | 30 s | Ammonium sulfite | DIW | 2 | 5 | DIW | 730.2 | 2235 | −3.82 |
| 7 | 30 s | Ammonium sulfite | DIW | 2 | 10 | DIW | 405.5 | 2390 | −6.49 |
| 9 | 30 s | Ammonium thiosulfate | DIW | 0.2 | 5 | DIW | 217 | 1104 | −27.16 |
| 10 | 30 s | Ammonium thiosulfate | DIW | 2 | 5 | DIW | 338 | 263 | −142.66 |
| 11 | 30 s | Ammonium thiosulfate | DIW | 10 | 5 | DIW | 199 | 901 | −37.18 |
| 12 | 30 s | Ammonium thiosulfate | DIW | 2 | 1 | DIW | 227 | 1370 | −20.05 |
| 13 | 30 s | Ammonium thiosulfate | DIW | 2 | 3 | DIW | 288 | 679 | −56.02 |
| 14 | 30 s | Ammonium thiosulfate | DIW | 2 | 5 | DIW | 325 | 601 | −24.26 |
| 15 | 30 s | Ammonium thiosulfate | DIW | 2 | 10 | DIW | 228.7 | 2455 | −11.18 |
| 17 | 30 s | Ammonium Sulfide | DIW | 2 | 5 | DIW | 234.1 | 2415 | −11.09 |
| 18 | 30 s | Ammonium Sulfide | DIW | 2 | 10 | DIW | 286.9 | 2663 | −8.19 |
| 20 | 30 s | Cysteine | DIW | 1 | 5 | DIW | 267 | 1145 | −20.72 |
| 21 | 30 s | Cysteine | DIW | 2 | 5 | DIW | 262.8 | 2415 | −9.89 |
| 22 | 30 s | Cysteine | DIW | 2 | 10 | DIW | 98.2 | 2660 | −23.90 |
| 23 | 30 s | Seleno-DL-methionine | DIW | 2 | 5 | DIW | 3006.5 | 2645 | −0.79 |
| 24 | 30 s | Seleno-DL-methionine | DIW | 2 | 10 | DIW | 4780.7 | 1155 | −1.60 |
| 26 | 30 s | Ammonium sulfite | IPA | 2 | 5 | IPA | 1327 | 1145 | −4.24 |
| 27 | 30 s | Ammonium thiosulfate | IPA | 2 | 5 | IPA | 3242 | 101 | −19.38 |
| 28 | 30 s | Ammonium Sulfide | IPA | 2 | 5 | IPA | 169 | 976 | −28.56 |
| 29 | 30 s | Cysteine | IPA | 2 | 5 | IPA | 214 | 1053 | −29.49 |

Substrates are analyzed by secondary ion mass spectrometry (SIMS) from two perspectives: 1) at the surface; and 2) as a function of depth, to determine the dopant concentration (in atoms/cm³) for the samples, and it is found that the sulfur concentration (in atoms/cm³) is >10¹⁹ at the surface and dropping below 10¹⁷ by 100 nm depth.

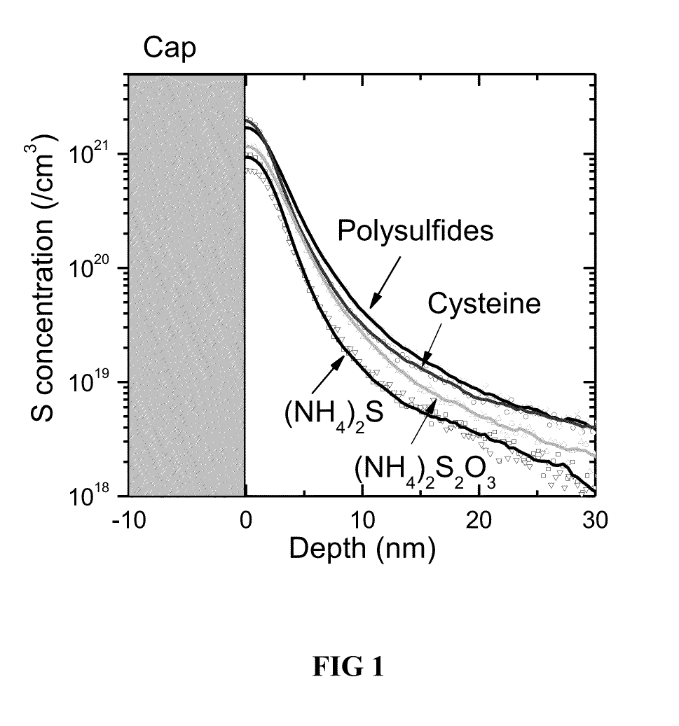

FIG. 1 shows a SIMS depth profile for Example #3 (shown as “Polysulfides” in FIG. 1), Example #15 (shown as “(NH₄)₂S₂O₃” in FIG. 1), Example #18 (shown as “(NH₄)₂S” in FIG. 1), and Example #22 (shown as “Cysteine” in FIG. 1), all from Table 1.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

As used herein, the terms “comprising” and “including” or grammatical variants thereof are to be taken as specifying the stated features, integers, steps or components but do not preclude the addition of one or more additional features, integers, steps, components or groups thereof. This term encompasses the terms “consisting of” and “consisting essentially of”.

The phrase “consisting essentially of” or grammatical variants thereof when used herein are to be taken as specifying the stated features, integers, steps or components but do not preclude the addition of one or more additional features, integers, steps, components or groups thereof but only if the additional features, integers, steps, components or groups thereof do not materially alter the basic and novel characteristics of the claimed composition, device or method.

All publications mentioned in this specification are herein incorporated by reference as if each individual publication were specifically and individually indicated to be incorporated by reference herein as though fully set forth.

Subject matter incorporated by reference is not considered to be an alternative to any claim limitations, unless otherwise explicitly indicated.

Where one or more ranges are referred to throughout this specification, each range is intended to be a shorthand format for presenting information, where the range is understood to encompass each discrete point within the range as if the same were fully set forth herein.

While several aspects and embodiments of the present invention have been described and depicted herein, alternative aspects and embodiments may be affected by those skilled in the art to accomplish the same objectives. Accordingly, this disclosure and the appended claims are intended to cover all such further and alternative aspects and embodiments as fall within the true spirit and scope of the invention.

1. A method for passivating a IV and/or III-V semiconductor material comprising exposing said material to an aqueous solution of a sulfur compound at a concentration between 0.001M and 10 M, wherein said sulfur compound is selected from a covalent sulfur compound, ammonium thiosulfate, and ammonium sulfite.

2. A method according to claim 1 wherein the sulfur compound is a covalent sulfur compound, and wherein said material is chosen from InGaAs and GaAs.

3. A method according to claim 1 wherein the sulfur compound is ammonium thiosulfate or ammonium sulfite, and wherein said material is chosen from InGaAs and GaAs.

4. A method according to claim 1 wherein the sulfur compound is a covalent sulfur compound, and wherein said covalent sulfur compound consists of sulfur, carbon, and from one to three additional elements chosen from hydrogen, oxygen and nitrogen.

5. A method according to claim 4 wherein said covalent sulfur compound is an organic mercaptan or thioether.

6. A method for making an n-region in a semiconductor comprising:
(a) providing a IV or III-V semiconductor material substrate;
(b) exposing said material to an aqueous solution of a sulfur compound at a concentration between 0.001M and 10 M to provide a semiconductor material having a surface layer containing sulfur, wherein said sulfur compound is selected from a covalent sulfur compound, ammonium thiosulfate, and ammonium sulfite;
(c) capping said surface layer containing sulfur; and
(d) annealing said semiconductor material having a capped surface layer containing sulfur, whereby sulfur diffuses into said IV or III-V semiconductor material.

7. A method according to claim 6 wherein the sulfur compound is a covalent sulfur compound, and wherein said material is chosen from InGaAs and GaAs.

8. A method according to claim 6 wherein the sulfur compound is ammonium thiosulfate or ammonium sulfite, and wherein said material is chosen from InGaAs and GaAs.

9. A method according to claim 6 wherein the sulfur compound is a covalent sulfur compound that consists of sulfur, carbon and from one to three additional elements chosen from hydrogen, oxygen and nitrogen.

10. A method according to claim 9 wherein said covalent sulfur compound is an organic mercaptan or thioether.

11. A method according to claim 6 wherein said surface layer containing sulfur is capped with silicon nitride.

12. A method according to claim 11 wherein said capped surface layer containing sulfur is annealed at a temperature from 300° C. to 1100° C.

13. A method for passivating a IV or III-V semiconductor material comprising exposing said material to an aqueous solution of a covalent selenium compound at a concentration between 0.001M and 10 M.

14. A method according to claim 13 wherein said material is InGaAs or GaAs.

15. A method for making an n-region in a semiconductor comprising:
(a) providing a IV or III-V semiconductor material substrate;
(b) exposing said material to an aqueous solution of a covalent selenium compound at a concentration between 0.001M and 10 M to provide a semiconductor material having a surface layer containing selenium;
(c) capping said surface layer containing selenium; and
(d) annealing said semiconductor material having a capped surface layer containing selenium, whereby selenium diffuses into said IV or III-V semiconductor material.

16. A method according to claim 15 wherein said material is chosen from Si, Ge, SiGe, GaAs, InP, InAs, GaP and ternary and quaternary alloys of GaAs, InP, InAs and GaP.

17. A method according to claim 16 wherein said material is InGaAs or GaAs.

18. A method according to claim 16 wherein said covalent selenium compound consists of selenium, carbon and from one to three additional elements chosen from hydrogen, oxygen and nitrogen.

19. A method according to claim 18 wherein said covalent selenium compound is an organic selenol or selenium ether.

20. A method according to claim 15 wherein said surface layer containing selenium is capped with silicon nitride, and wherein said capped surface layer containing selenium is annealed at a temperature from 300° C. to 1100° C.
